(19) United States
(12) Patent Application Publication
(10) Pub. No.: US 2026/0011662 A1
(43) Pub. Date: Jan. 8, 2026

(54) DISPLAY DEVICE AND ELECTRONIC DEVICE

(71) Applicant: SAMSUNG DISPLAY CO., LTD., YONGIN-SI (KR)

(72) Inventor: CHANG HO HYUN, Yongin-si (KR)

(21) Appl. No.: 19/256,276

(22) Filed: Jul. 1, 2025

(30) Foreign Application Priority Data
Jul. 5, 2024 (KR) 10-2024-0088763

(51) Int. Cl. H01L 23/60; H10K 59/95

(52) U.S. Cl. CPC H01L 23/60; H10K 59/95

(57) ABSTRACT

A display device includes a display panel. A main circuit board has a recessed part that is recessed in a thickness direction of the display panel. A connection circuit board is electrically connected to the display panel on a first side of the connection circuit board and electrically connected to the main circuit board on a second side of the connection circuit board opposite to the first side. A driving chip is mounted on the second side of the connection circuit board and is disposed in the recessed part. The main circuit board includes a shielding layer overlapping the recessed part.

### CROSS-REFERENCE TO RELATED APPLICATIONS

This application claims priority under 35 U.S.C. § 119 to Korean Patent Application No. 10-2024-0088763, filed on Jul. 5, 2024 in the Korean Intellectual Property Office, the disclosure of which is incorporated by reference in its entirety herein.

### 1. TECHNICAL FIELD

The present disclosure herein relates to a display device, and more particularly, a display device with increased reliability.

### 2. DISCUSSION OF RELATED ART

Research is presently being conducted to develop various types of display devices. The display devices are applied to various different multi-media apparatuses, including televisions, mobile phones, tablet computers, navigation systems, game consoles, etc. The display device includes a display panel displaying images, and circuit boards coupled to the display panel to provide driving signals to the display panel. The display panel includes a display part displaying the images, and panel pads disposed on the outer part of the panel to provide the driving signals to the display part.

The circuit boards may be electrically connected to each other through the pads. For example, when the pads of the circuit board, the pads of the display panel, and the pads of each of the circuit boards connected to each other are fully electrically connected to each other, control signals and image signals may be transferred to the display panel without distortion.

### SUMMARY

The present disclosure provides a display device capable of protecting a driving chip included therein from external static electricity.

According to an embodiment of the present inventive concept, a display device includes a display panel. A main circuit board has a recessed part that is recessed in a thickness direction of the display panel. A connection circuit board is electrically connected to the display panel on a first side of the connection circuit board and electrically connected to the main circuit board on a second side of the connection circuit board opposite to the first side. A driving chip is mounted on the second side of the connection circuit board and is disposed in the recessed part. The main circuit board includes a shielding layer overlapping the recessed part.

According to an embodiment of the present inventive concept, a display device includes a display panel. A main circuit board has a recessed part that is recessed in a thickness direction of the display panel. A connection circuit board is electrically connected to the display panel on a first side of the connection circuit board and electrically connected to the main circuit board on a second side of the connection circuit board opposite to the first side. A driving chip is mounted on the second side of the connection circuit board and is disposed in the recessed part. The main circuit board includes a shielding pattern surrounding the driving chip on a plane.

According to an embodiment of the present inventive concept, a display device includes a display panel including first to third regions spaced apart from each other. The first region includes a pixel. The second region is bendable with respect to a virtual axis extending in a first direction. The third region includes a driving chip mounted thereon. The driving chip is electrically connected to the pixel. A circuit board includes a recessed part that is recessed in a thickness direction of the display panel. The driving chip is disposed in the recessed part. The circuit board includes a shielding layer overlapping the recessed part.

According to an embodiment of the present inventive concept, an electronic device includes a display device. An electronic module overlaps the display device. A housing accommodates the display device. The display device includes a display panel. A main circuit board has a recessed part that is recessed in a thickness direction of the display panel. A connection circuit board is electrically connected to the display panel on a first side of the connection circuit board and electrically connected to the main circuit board on a second side of the connection circuit board opposite to the first side. A driving chip is mounted on the second side of the connection circuit board and is disposed in the recessed part. The main circuit board includes a shielding layer overlapping the recessed part.

### BRIEF DESCRIPTION OF THE DRAWINGS

The accompanying drawings are included to provide a further understanding of the present inventive concept, and are incorporated in and constitute a part of this specification. The drawings illustrate embodiments of the present inventive concept and, together with the description, serve to explain principles of the present inventive concept. In the drawings:

FIG. 1 is a perspective view of an electronic device according to an embodiment of the present inventive concept;

FIG. 2 is an exploded perspective view of an electronic device according to an embodiment of the present inventive concept;

FIG. 3 is a plan view of a display device according to an embodiment of the present inventive concept;

FIGS. 4A and 4B are cross-sectional views each illustrating a display device according to an embodiment of the present inventive concept;

FIG. 5 is a cross-sectional view of a display module according to an embodiment of the present inventive concept;

FIG. 6 is an enlarged view of region AA′ illustrated in FIG. 4B according to an embodiment of the present inventive concept;

FIGS. 7A and 7B are plan views of region AA′ of FIG. 6 viewed from a third direction according to embodiments of the present inventive concept;

FIG. 8A is an enlarged view partially illustrating a display device according to an embodiment of the present inventive concept;

FIG. 8B is a plan view of region AA′ of FIG. 8A viewed from a third direction according to an embodiment of the present inventive concept;

FIGS. 9A and 9B are cross-sectional views each illustrating a display device according to an embodiment of the present inventive concept; and

FIGS. 10A and 10B are cross-sectional views each illustrating a display device according to an embodiment of the present inventive concept.

FIG. 11 is a diagram illustrating an electronic device according to an embodiment of the present inventive concept.

### DETAILED DESCRIPTION OF EMBODIMENTS

Embodiments of the present inventive concept will be described below in more detail with reference to the accompanying drawings. The present inventive concept may, however, be embodied in different forms and should not be construed as limited to the described embodiments set forth herein.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween. When an element is referred to as being “directly on”, “directly connected to” or “directly coupled to” another element, no intervening elements may be disposed therebetween.

Like reference numerals or symbols refer to like elements throughout. In the drawings, the thickness, the ratio, and the size of the element may be exaggerated for effective description of the technical contents.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the present inventive concept. Similarly, a second element, component, region, layer or section may be termed a first element, component, region, layer or section. In this specification “a”, “an” and “the” are intended to include the plural forms as well, unless the context clearly indicates otherwise.

In addition, terms of “below”, “on lower side”, “above”, “on upper side”, or the like may be used to describe the relationships of the elements illustrated in the drawings. These terms have relative concepts and are described on the basis of the directions indicated in the drawings.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes/including” and/or “have/having”, when used in this specification, specify the presence of stated features, integers, steps, operations, elements, components, and/or a group thereof, but do not preclude the presence or addition of one or more other features, integers, steps, operations, elements, components, and/or groups thereof.

Hereinafter, embodiments of the present inventive concept will be described with reference to the accompanying drawings.

The present inventive concept relates to a display device that includes a main circuit board having a recessed part in which a driving chip is disposed therein. A shielding layer may overlap the driving chip disposed in the recessed part on a plane. A plurality of shielding patterns may surround the driving chip disposed in the recessed part on a plane. The driving chip disposed in the recessed part may be protected from external static electricity by the plurality of shielding patterns and the shielding layer. Additionally, the display device may not need a separate cover space for the protection of the driving chip. Thus, the display device may have increased reliability and a simplified manufacturing process.

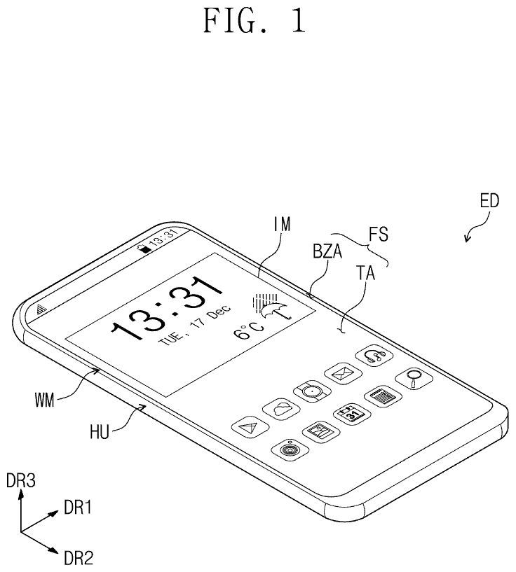

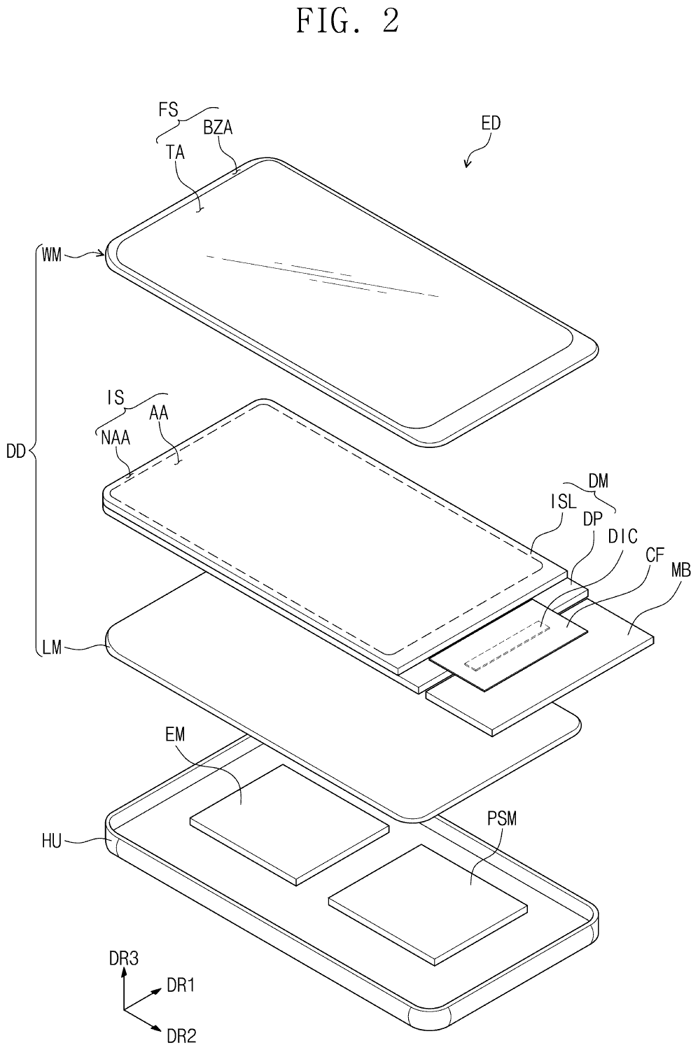

FIG. 1 is a perspective view of an electronic device according to an embodiment of the present inventive concept. FIG. 2 is an exploded perspective view of an electronic device according to an embodiment of the present inventive concept.

An electronic device ED may be activated in response to electrical signals. The electronic device ED may include various embodiments. For example, in some embodiments the electronic device ED may be applied to an electronic device such as a mobile phone, a smart watch, a tablet computer, a laptop computer, a computer, and a smart television. A display device according to an embodiment of the present inventive concept may not necessarily be limited to the above-mentioned examples, and may also be employed in another electronic device as long as it does not deviate from the present inventive concept. In this embodiment, the electronic device ED is exemplarily illustrated as a mobile phone.

The electronic device ED may display an image IM on a display surface FS parallel to each of a first direction DR1 and a second direction DR2 toward a third direction DR3. The display surface FS on which the image IM is displayed may correspond to a front surface of a display device DD. The image IM may include at least one still image and/or at least one dynamic image (e.g., moving image). FIG. 1 illustrates software application icons and a clock, temperature and calendar window as an example of the image IM. However, embodiments of the present inventive concepts are not necessarily limited thereto and the image IM may be various different subject matter.

In this embodiment, a front surface (e.g., an upper surface) and a rear surface (e.g., a lower surface) of each of members are defined on the basis of a direction in which the image IM is displayed. The front surface and the rear surface may be opposed to each other in the third direction DR3, and the normal direction of each of the front surface and the rear surface may be parallel to the third direction DR3. A distance between the front surface and the rear surface in the third direction DR3 may correspond to the thickness of the display device DD in the third direction DR3. In this specification, “on a plane” may mean when viewed from the third direction DR3. Directions indicated by the first to third directions DR1, DR2, and DR3 may have relative concepts, and may thus be changed to other directions.

The electronic device ED may detect an external input applied from the outside (e.g., the external environment). The external input may include various types of inputs provided from the outside of the electronic device ED. For example, in an embodiment the external input may include not only an external input applied by contact of a part of a user's body such as a hand, but also an external input applied in proximity to, or adjacent at a predetermined distance to the electronic device ED (for example, hovering). In addition, the external input may have various forms such as power, pressure, temperature, and light.

The electronic device ED may include a window WM and a housing HU. The window WM and the housing HU may be coupled to each other to form an exterior of the electronic device ED.

The window WM may be divided into a transmission region TA and a bezel region BZA. The front surface of the electronic device ED may correspond to the transmission region TA and the bezel region BZA of the window WM.

The transmission region TA may be a region where the image IM is displayed. The transmission region TA may be an optically transparent region. A user may view the image IM through the transmission region TA.

In this embodiment, the transmission region TA is illustrated as a quadrilateral shape with rounded corners. However, embodiments of the present inventive concept are not necessarily limited thereto and the transmission region TA may have various different shapes.

The bezel region BZA may be a region which is relatively low in light transmittance, compared to the transmission region TA. For example, the bezel region BZA may be provided as a region printed with a material containing a predetermined color.

The bezel region BZA may be a region adjacent to the transmission region TA. The bezel region BZA may surround the transmission region TA (e.g., in a plan view). Accordingly, the shape of the transmission region TA may be substantially defined by the bezel region BZA. However, embodiments of the present disclosure are not necessarily limited thereto, and the bezel region BZA may also be disposed adjacent to only one side of the transmission region TA, and may also be omitted.

Referring to FIGS. 1 and 2 together, in an embodiment the electronic device ED may include the display device DD, an electronic module EM, a power module PSM, and the housing HU. FIG. 2 briefly illustrates the electronic device ED, and the electronic device ED may further include a mechanical structure (e.g., a hinge) for controlling operation of the display device DD (e.g., folding or rolling).

In an embodiment, the display device DD includes the window WM, the display module DM, a lower member LM, a driving chip DIC, a connection circuit board CF, and a main circuit board MB. The display module DM may include a display panel DP and an input-sensing layer ISL.

The window WM may be disposed on the display module DM (e.g., disposed directly thereon in the third direction DR3). The window WM may protect the display module DM. The window WM may include an optically transparent material. For example, in an embodiment the window WM may include glass, sapphire, plastic, etc. An image provided from the display module DM may be provided to a user through the window WM.

The window WM may have a single-layer or multi-layer structure. For example, the window WM may include a plurality of plastic films coupled to each other, or a glass substrate and a plastic film coupled to each other.

The display module DM may include a front surface IS having an active region AA and a peripheral region NAA. The active region AA may be a region activated in response to electrical signals. In an embodiment, the active region AA may be a region where the image IM is displayed, and at the same time, where the external input is detected.

The transmission region TA may overlap at least a portion of the active region AA (e.g., in the third direction DR3). Accordingly, a user may view the image IM, or provide the external input through the transmission region TA. However, embodiments of the present inventive concept are not necessarily limited thereto and the region where the image IM is displayed and the region where the external input is detected may also be separated in the active region AA, and the active region AA, etc.

The peripheral region NAA may be a region covered by the bezel region BZA. The peripheral region NAA is adjacent to the active region AA (e.g., in the first and/or second directions DR1, DR2). The peripheral region NAA may surround the active region AA (e.g., in a plan view). A driving circuit, a driving wire, or the like for driving the active region AA may be disposed in the peripheral region NAA.

The display panel DP according to an embodiment of the present inventive concept may be a liquid crystal display panel or an emission-type display panel. However, embodiments of the present inventive concept are not necessarily limited thereto. For example, in an embodiment the emission-type display panel may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like.

In an embodiment, the display panel DP may be flexible. The meaning of being “flexible” may indicate bendable characteristics, and may include everything from a completely foldable structure to a partially bendable structure. For example, the display panel DP may be a curved display panel or a foldable display panel. An embodiment of the present inventive concept is not necessarily limited thereto, and the display panel DP may be a rigid display panel.

The input-sensing layer ISL may be disposed on the display panel DP. In an embodiment, as illustrated in FIG. 2, the input-sensing layer ISL may be directly disposed on the display panel DP (e.g., in the third direction DR3). For example, the input-sensing layer ISL may be formed on the display panel DP through a continuous process, and an adhesive film may not be disposed between the input-sensing layer ISL and the display panel DP (e.g., in the third direction DR3). However, embodiments of the present inventive concept are not necessarily limited thereto, and the adhesive film may be disposed between the input-sensing layer ISL and the display panel DP in some embodiments. For example, the input-sensing layer ISL may be manufactured in a separate process from that of the display panel DP, and then may be fixed on an upper surface of the display panel DP by the adhesive film.

The input-sensing layer ISL may detect an external input applied from the outside (e.g., the external environment). As previously described, the input-sensing layer ISL may detect the external input provided onto the window WM.

The connection circuit board CF may connect (e.g., electrically connect) the display panel DP and the main circuit board MB to each other. In an embodiment, the connection circuit board CF may be electrically connected to the display panel DP on one side (e.g., a first side) adjacent to the display panel DP. The connection circuit board CF may be electrically connected to the main circuit board MB on the other side (e.g., an opposite second side second side) adjacent to the main circuit board MB. For example, in an embodiment an upper side (e.g., in a direction opposite to the second direction DR2) of the connection circuit board CF may be a first side that is physically and electrically connected to the display panel DP and a lower side (e.g., in the second direction DR2) of the connection circuit board CF may be a second side that is physically and electrically connected to the main circuit board MB.

In this embodiment, it is illustrated that one connection circuit board CF connects the display panel DP and the main circuit board MB to each other, but embodiments of the present inventive concept are not necessarily limited thereto, and the connection circuit board may be provided in plurality to connect (e.g., electrically connect) the display panel DP and the main circuit board MB to each other.

In an embodiment, the connection circuit board CF may be a flexible printed circuit board which is flexible. The connection circuit board CF may provide electrical signals to the display panel DP to drive the display panel PD. The electrical signals may be generated from the connection circuit board CF or from the main circuit board MB.

In an embodiment, the driving chip DIC may be mounted under the connection circuit board CF (e.g., directly thereunder in a direction opposite to the third direction DR3). However, unlike what is illustrated in the drawing, in some embodiments the driving chip DIC may be mounted on the connection circuit board CF (e.g., directly thereon in the third direction DR3). The driving chip DIC may be mounted on the flexible printed circuit board to form a chip on film (COF). In an embodiment, the driving chip DIC may be mounted on the second side of the connection circuit board CF.

The driving chip DIC may include driving elements for driving a pixel of the display panel DP. In an embodiment, the driving chip DIC may include a driving circuit, and the driving circuit may be provided as an integrated circuit. The driving circuit may include a driving controller, a data driver, a voltage generator, etc.

The main circuit board MB may include a main controller. In an embodiment, the main circuit board MB may include signal wires for transferring control signals and image signals, received from the main controller, to the connection circuit board CF and the display panel DP. The main circuit board MB may be a rigid printed circuit board or a flexible printed circuit board.

In an embodiment, an input circuit board, which is electrically connected to the input-sensing layer ISL, may be further included. The input circuit board may connect (e.g., electrically connect) the input-sensing layer ISL and the main circuit board MB to each other. In this embodiment, the input circuit board may be provided as a flexible circuit film, and may thus connect (e.g., electrically connect) the input-sensing layer ISL and the main circuit board MB to each other. The input circuit board provides electrical signals for driving the input-sensing layer ISL to the input-sensing layer ISL. The electrical signals may be generated from the input circuit board or from the main circuit board MB.

In an embodiment, the connection circuit board CF and the input circuit board may each be connected to one main circuit board MB. Any one among the connection circuit board CF and the input circuit board may not be connected to the main circuit board MB, and the configuration is not necessarily limited to any one embodiment of the present inventive concept.

The lower member LM may be disposed under the display panel DP (e.g., in a direction opposite to the third direction DR3). In an embodiment, the lower member LM may include a protection film that protects the display panel DP, a supporting member that supports the display panel DP, a digitizer, and the like.

In an embodiment, the electronic module EM may include a control module, a wireless communication module, an image input module, a sound input module, a sound output module, a memory, an external interface module, and the like. The electronic module EM may include a main circuit board, and the modules may be mounted on the main circuit board, or electrically connected to the main circuit board through a flexible printed circuit board. The electronic module EM is electrically connected to the power module PSM.

In an embodiment, the electronic device ED may further include an electronic optical module. The electronic optical module may be an electronic component that outputs or receives optical signals. The electronic optical module may include a camera module and/or a proximity sensor. The camera module may capture an external image through a partial region of the display panel DP.

The housing HU illustrated in FIG. 2 is coupled to the display device DD, particularly to the window WM, to accommodate the above-mentioned different modules. The housing HU is illustrated to have an integrated form. However, embodiments of the present inventive concept are not necessarily limited thereto. For example, in an embodiment the housing HU may include a plurality of portions coupled to each other (e.g., a side border portion and a bottom portion). The housing HU may protect the display module DM, accommodated in an inner space, from external impact, and may prevent foreign substances or moisture from penetrating the display module DM.

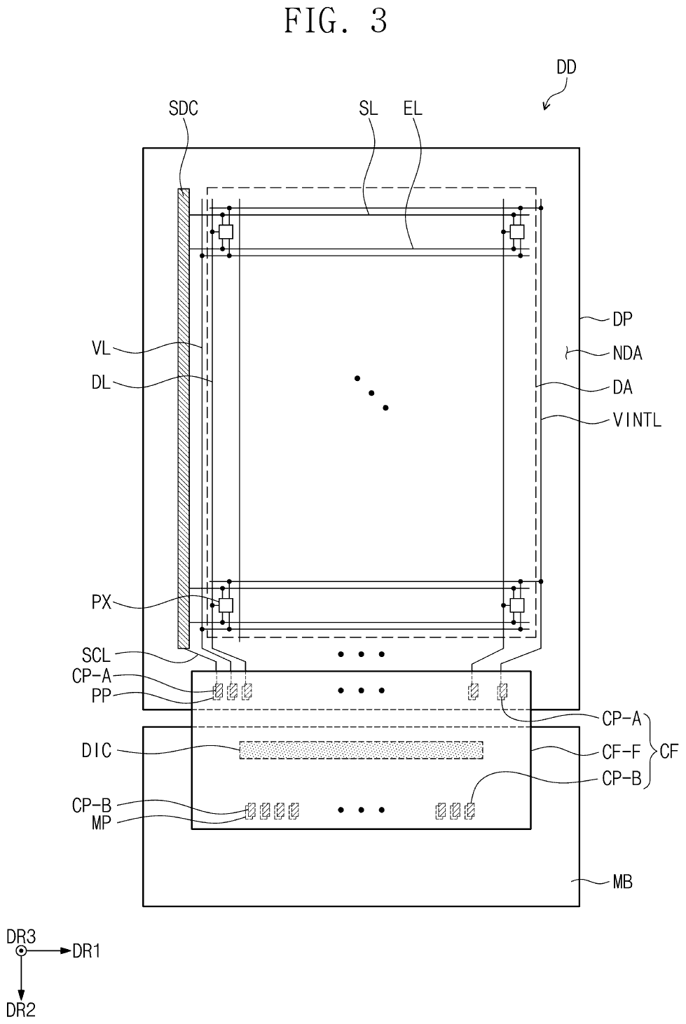

FIG. 3 is a plan view of a display device according to an embodiment of the present inventive concept.

Referring to FIG. 3, a display region DA and a non-display region NDA may be defined in a display panel DP on a plane. The display region DA may be a region where an image is displayed. The non-display region NDA may be a region where an image is not displayed. The non-display region NDA may be adjacent to the display region DA (e.g., in the first and/or second direction DR1, DR2). The non-display region NDA may surround the display region DA (e.g., in a plan view), but the shape is not necessarily limited thereto.

In an embodiment, the display panel DP may include a plurality of pixels PX, a scan driving circuit SDC, a plurality of signal lines, and a plurality of panel pads PP. In an embodiment, the signal lines included in the display panel DP may include signal lines, scan lines SL, emission lines EL, data lines DL, a scan control line SCL, an initialization voltage line VINTL, and a voltage line VL.

The pixels PX may each include a display element and a thin-film transistor electrically connected to the display element. The display element may include, for example, an organic light-emitting diode. The pixels PX may be disposed in the display region DA. However, embodiment of the present inventive concept are not necessarily limited thereto, and some of the pixels PX may also be disposed in the non-display region NDA.

In an embodiment, the pixels PX may be disposed in the form of a matrix along a first direction DR1 and a second direction DR2 perpendicular to each other. In an embodiment of the present inventive concept, the pixels PX may include first to third pixels that display red color, green color, and blue color, respectively. In an embodiment, the pixels PX may further include some pixels that display white, cyan, and magenta, respectively. However, embodiments of the present inventive concept are not necessarily limited thereto and the colors of the light emitted by the pixels PX may vary.

The scan driving circuit SDC may be disposed adjacent to one side of the non-display region NDA. For example, as shown in FIG. 3 the scan driving circuit SDC may be disposed adjacent to the left side of the non-display region NDA (e.g., in a direction opposite to the first direction DR1). However, embodiments of the present inventive concept are not necessarily limited thereto and the positioning of the scan driving circuit SDC may vary, and the scan driving circuit SDC may also be disposed in the display region DA. The scan driving circuit SDC may generate a plurality of scan signals, and may sequentially output the generated scan signals through the scan lines SL to be described later. The scan driving circuit SDC may further output other control signals to driving circuits of the pixels PX.

In an embodiment, the scan lines SL may extend longitudinally from the scan driving circuit SDC along the first direction DR1, and may each be connected to a corresponding pixel among the plurality of pixels PX. The emission lines EL may extend longitudinally from the scan driving circuit SDC along the first direction DR1, and may each be arranged alongside a corresponding scan line among the scan lines SL. The scan lines SL and the emission lines EL may be connected to the scan driving circuit SDC.

In an embodiment, the data lines DL may extend longitudinally along the second direction DR2, and may each be connected to a corresponding pixel PX among the plurality of pixels PX. The scan control line SCL may provide control signals to the scan driving circuit SDC.

The initialization voltage line VINTL may provide an initialization voltage to the plurality of pixels PX. The voltage line VL may be connected to the plurality of pixels PX, and may provide voltages to the plurality of pixels PX. In an embodiment, the voltage line VL may include a plurality of lines extending longitudinally along the first direction DR1 and a plurality of lines extending longitudinally along the second direction DR2.

Some of the scan lines SL, the data lines DL, the emission lines EL, the scan control line SCL, the initialization voltage line VINTL, and the voltage line VL may be disposed on the same layer as each other, and others may be disposed on a different layer from each other.

The panel pads PP may be arranged in the non-display region NDA. In an embodiment, the panel pads PP may be arranged side by side each other in the first direction DR1. In this embodiment, it is illustrated and described that the panel pads PP are arranged in a row along the first direction DR1. However, embodiments of the present inventive concept are not necessarily limited thereto. For example, the panel pads PP may be arranged in two or more rows, or arranged in a staggered manner. The panel pads PP may be connected to the data lines DL, the scan control line SCL, the initialization voltage line VINTL, and the voltage line VL.

In an embodiment, the connection circuit board CF may include a connection base layer CF-F, a plurality of panel connecting pads CP-A, and a plurality of board connecting pads CP-B.

The connection base layer CF-F may be an insulation layer on which the plurality of panel connecting pads CP-A and the plurality of board connecting pads CP-B are disposed. The connection base layer CF-F may include a flexible film.

In an embodiment, the panel connecting pads CP-A may be arranged along the first direction DR1 on one side (e.g., a first side) adjacent to the display panel DP (e.g., an upper side in the a direction opposite to the second direction DR2). The panel connecting pads CP-A may be connected to the panel pads PP of the display panel DP respectively corresponding to the panel connecting pads CP-A.

In an embodiment, the panel pads PP may be arranged on a front surface of the display panel DP, and the panel connecting pads CP-A may be arranged on a rear surface of the connection base layer CF-F. However, embodiments of the present inventive concept are not necessarily limited thereto, and in some embodiments the panel pads PP may be arranged on a rear surface of the display panel DP, and the panel connecting pads CP-A may be arranged on a front surface of the connection base layer CF-F.

The board connecting pads CP-B may be arranged along the first direction DR1 on the other side (e.g., a second side) adjacent to the main circuit board MB (e.g., a lower side in the second direction DR2). The board connecting pads CP-B may be spaced apart from the panel connecting pads CP-A along the second direction DR2. In an embodiment, the board connecting pads CP-B may be arranged on the rear surface of the connection base layer CF-F. However, embodiments of the present inventive concept are not necessarily limited thereto, and in some embodiments the board connecting pads CP-B may be arranged on the front surface of the connection base layer CF-F.

In an embodiment, the connection circuit board CF may include multiple wires. Each of the multiple wires may transmit electrical signals to components connected to one end and the other end thereof. The multiple wires may include wires electrically connecting the panel connecting pads CP-A to the driving chip DIC, and wires electrically connecting the board connecting pads CP-B to the driving chip DIC. The multiple wires may be disposed on the connection base layer CF-F.

The main circuit board MB may include a plurality of board pads MP. In an embodiment, the main circuit board MB may include multiple wires connected to the board pads MP.

The board pads MP may be arranged along the first direction DR1 on one side adjacent to the connection circuit board CF (e.g., a lower side in the second direction DR2). In an embodiment, the board pads MP may be arranged on a front surface of the main circuit board MB. However, embodiments of the present inventive concept are not necessarily limited thereto, and the board pads MP may be arranged on a rear surface of the main circuit board MB in some embodiments.

The board pads MP may be connected to the board connecting pads CP-B of the connection circuit board CF respectively corresponding to the board pads MP. In an embodiment, each of the board connecting pads CP-B may be electrically connected to a main controller through the wires, and may receive control signals and image signals from the main controller. The board pads MP may transfer the received signals to the board connecting pads CP-B.

FIG. 3 illustrates the pads being arranged in a staggered manner for easier understanding of the connection between the panel pads PP and the panel connecting pads CP-A, and the connection between the board pads MP and the board connecting pads CP-B. However, embodiments of the present inventive concept are not necessarily limited thereto and the pads may each be connected to a corresponding pad by overlapping each other (e.g., in the third direction DR3).

When the panel pads PP and the panel connecting pads CP-A are fully and completely connected (e.g., electrically connected), control signals and image signals, transferred from a driving circuit of the driving chip DIC, may be transferred to the display panel DP without distortion. When the board pads MP and the board connecting pads CP-B are fully and completely connected, control signals and image signals, received from the main controller of the main circuit board MB, may be transferred to the driving circuit of the driving chip DIC without distortion.

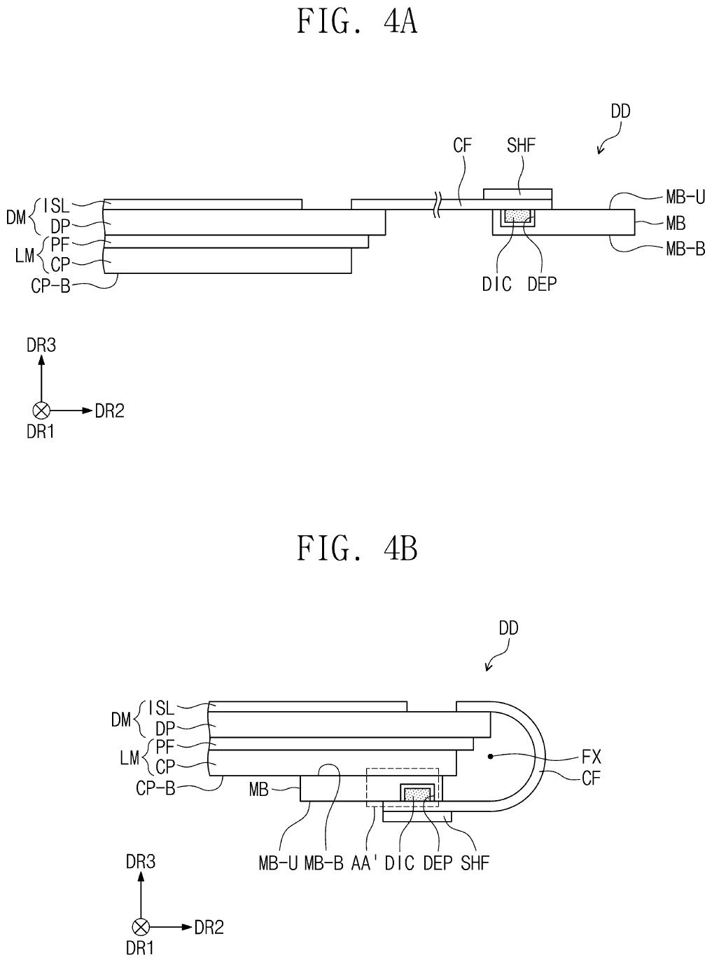

FIGS. 4A and 4B are cross-sectional views each illustrating a display device according to an embodiment of the present inventive concept. In particular, FIG. 4A illustrates a cross section of the display device DD illustrated in FIG. 3, and FIG. 4B is a drawing illustrating a bent state of the display device DD of FIG. 4A. Hereinafter, duplicate contents or those previously described will be omitted.

Referring to FIG. 4A, a lower member LM may include a lower film PF (e.g., a protection film) and a cover panel CP. According to an embodiment of the present inventive concept, the lower member LM may further include a supporting plate and a digitizer.

The cover panel CP may be disposed under the lower film PF (e.g., in a direction opposite to the third direction DR3). The cover panel CP may increase resistance against compression force which is generated by external pressing. Therefore, the cover panel CP may serve to prevent deformation of a display module DM. In an embodiment, the cover panel CP may include a flexible plastic material such as polyimide or polyethylene terephthalate. In addition, the cover panel CP may be a colored film which is low in light transmittance. The cover panel CP may absorb light incident from the outside (e.g., the external environment). For example, in an embodiment the cover panel CP may be a black synthetic resin film.

In an embodiment, the supporting plate may also be further disposed under the cover panel CP (e.g., in a direction opposite to the third direction DR3). The supporting plate may include a metal material with relatively high strength. The supporting plate may also include a reinforced fiber composite material. The supporting plate may include a reinforced fiber disposed inside a matrix part. The reinforced fiber may be a carbon fiber or glass fiber. The matrix part may include a polymer resin. The matrix part may include a thermoplastic resin. For example, in an embodiment the matrix part may include a polyamide-based resin or a polypropylene-based resin. For example, the reinforced fiber composite material may be carbon fiber reinforced plastic (CFRP) or glass fiber reinforced plastic (GFRP).

According to an embodiment of the present inventive concept, a recessed part DEP may be defined in a main circuit board MB. The recessed part DEP may be recessed from an upper surface of the main circuit board MB in an opposite direction of a third direction DR3 (e.g., when the connection circuit board CF is in an unbent state). The recessed part DEP may be recessed in a thickness direction of the display module DM. In an embodiment, the recessed part DEP may have a quadrilateral shape in a cross-sectional view. However, embodiments of the present inventive concept are not necessarily limited thereto, and the recessed part DEP may have various shapes in the cross-sectional view, such as a half-sphere or triangle shape. A driving chip DIC may be disposed in the recessed part DEP, such as the driving chip DIC mounted on the second side of the connection circuit board CF. In an embodiment, a depth of the recessed part DEP (e.g., in the third direction DR3) may be greater than a thickness of the driving chip DIC (e.g., in the third direction DR3) so that an entirety of the driving chip DIC is disposed within the recessed part DEP. This will be described in detail later.

Referring to FIGS. 4A and 4B together, according to an embodiment of the present inventive concept, a connection circuit board CF may be bendable in a direction towards a rear surface of a display panel DP with a predetermined curvature. For example, in an embodiment the connection circuit board CF may be bendable with respect to a bending axis FX parallel to a first direction DR1. At this time, the main circuit board MB may be disposed on the rear surface of the display panel DP. For example, in an embodiment, the main circuit board MB may be disposed on a rear surface CP-B of the cover panel CP when the connection circuit board CF is in a bent state.

According to an embodiment of the present inventive concept, the main circuit board MB may include an upper surface MB-U and a rear surface MB-B opposed to each other (e.g., in the third direction DR3). When the connection circuit board CF is bent in the direction towards the rear surface of the display panel DP, the rear surface MB-B of the main circuit board MB may face the rear surface CP-B of the cover panel CP to be connected to each other (e.g., directly connected thereto).

The display device DD according to an embodiment of the present inventive concept may further include a shielding film SHF disposed on the connection circuit board CF (e.g., disposed directly thereon). For example, the shielding film SHF may be disposed directly on an upper surface of the connection circuit board CF when the connection circuit board CF is in an unbent state. The shielding film SHF may overlap the driving chip DIC on a plane. In an embodiment, the shielding film SHF may face the driving chip DIC with the connection circuit board CF therebetween (e.g., in the third direction DR3). Referring to FIG. 4B, since the shielding film SHF overlaps the driving chip DIC on a plane, the driving chip DIC may be protected from static electricity generated from the electronic module EM, the power module PSM, and the like illustrated in FIG. 2.

The display device DD according to an embodiment of the present inventive concept may further include a conductive adhesion member. The conductive adhesion member may be disposed between the display panel DP and the connection circuit board CF, and between the connection circuit board CF and the main circuit board MB. The conductive adhesion member may bond the panel pads PP and the panel connecting pads CP-A of the connection circuit board CF, illustrated in FIG. 3, to each other. In addition, the conductive adhesion member may bond the board pads MP of the main circuit board MB and the board connecting pads CP-B of the connection circuit board CF, illustrated in FIG. 3, to each other.

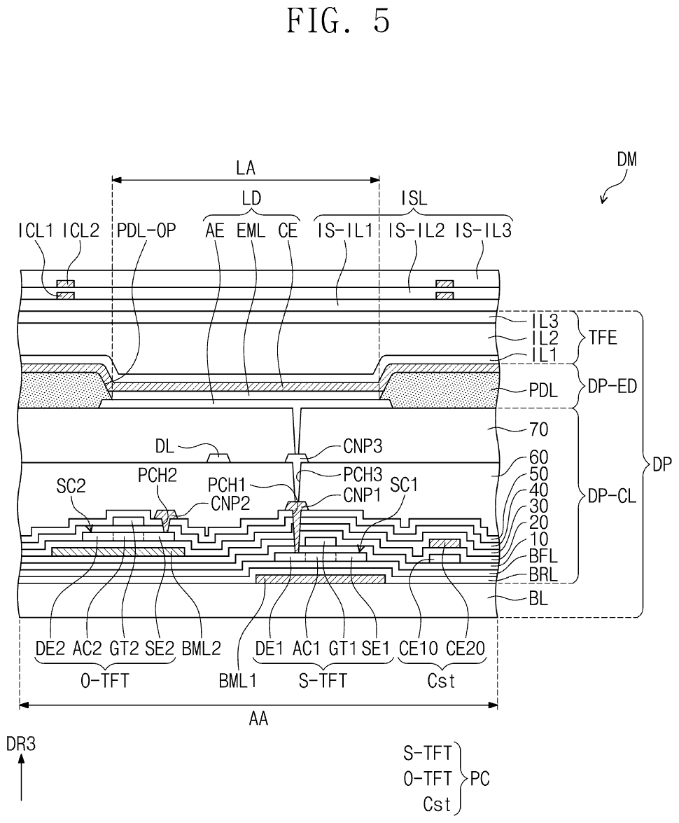

FIG. 5 is a cross-sectional view of a display module according to an embodiment of the present inventive concept. For example, FIG. 5 illustrates a cross section of a display module DM corresponding to the pixel PX of FIG. 3.

Referring to FIG. 5, a pixel driving circuit PC that drives a light-emitting element LD may include a plurality of pixel driving elements. In an embodiment, the pixel driving circuit PC may include a plurality of transistors S-TFT and O-TFT and a capacitor Cst. The plurality of transistors S-TFT and O-TFT may include a silicon transistor S-TFT and an oxide transistor O-TFT. FIG. 5 exemplarily illustrates the silicon transistor S-TFT and the oxide transistor O-TFT. However, embodiments of the present inventive concept are not necessarily limited thereto and the pixel driving circuit may vary from the pixel driving circuit PC shown in FIG. 5. The pixel driving circuit PC may also include either one of the silicon transistor S-TFT or the oxide transistor O-TFT.

In FIG. 5, a base layer BL is illustrated as a single layer. The base layer BL may include a synthetic resin such as polyimide. In an embodiment, a synthetic resin layer may be applied onto a working substrate (e.g., a carrier substrate) to form the base layer BL. After the follow-up process is performed and the display module DM is completed, the working substrate may be removed.

A first shielding electrode BML1 (e.g., a shielding electrode) may be disposed on the base layer BL (e.g., disposed directly thereon in the third direction DR3). The first shielding electrode BML1 may receive a bias voltage. The first shielding electrode BML1 may also receive a first power voltage. The first shielding electrode BML1 may block electric potential caused by polarization from affecting the silicon transistor S-TFT. The first shielding electrode BML1 may block external light from reaching the silicon transistor S-TFT. According to an embodiment of the present inventive concept, the first shielding electrode BML1 may also be a floating electrode that is electrically isolated from all other electrodes or wires. The first shielding electrode BML1 may be disposed in correspondence to the silicon transistor S-TFT. For example, the first shielding electrode BML1 may overlap the silicon transistor S-TFT (e.g., in the third direction DR3). The first shielding electrode BML1 may include metal, for example, molybdenum.

A barrier layer BRL may be disposed on (e.g., disposed directly thereon) the base layer BL and the first shielding electrode BML1. The barrier layer BRL prevents foreign substances from entering from the outside (e.g., the external environment). The barrier layer BRL may include at least one inorganic layer. In an embodiment, the barrier layer BRL may include a silicon oxide layer and a silicon nitride layer. Each of these may be provided in plurality, and the silicon oxide layers and the silicon nitride layers may be alternately stacked (e.g., in the third direction DR3).

A buffer layer BFL may be disposed on the barrier layer BRL (e.g., disposed directly thereon in the third direction DR3). The buffer layer BFL may prevent dispersion of metal atoms or impurities from the base layer BL to a first semiconductor pattern SC1 thereabove. In an embodiment, the buffer layer BFL may include at least one inorganic layer. The buffer layer BFL may include a silicon oxide layer and a silicon nitride layer.

The first semiconductor pattern SC1 may be disposed on the buffer layer BFL (e.g., disposed directly thereon in the third direction DR3). The first semiconductor pattern SC1 may include a silicon semiconductor. For example, in an embodiment the silicon semiconductor may include amorphous silicon, polycrystalline silicon, etc. For example, the first semiconductor pattern SC1 may include low-temperature polysilicon.

The first semiconductor pattern SC1 may vary in electrical property according to whether it is doped or not. The first semiconductor pattern SC1 may include a first region with high conductivity, and a second region with low conductivity. The first region may be doped with an N-type dopant or a P-type dopant. A P-type transistor may include a region doped with the P-type dopant, and an N-type transistor may include a region doped with the N-type dopant. The second region may be an undoped region, or a region doped with lower concentration than the first region. In this embodiment, the first semiconductor pattern SC1 may be the N-type transistor.

The conductivity of the first region may be higher than the conductivity of the second region, and substantially, the first region may serve as an electrode or a signal line. The second region may substantially correspond to a channel region (e.g., an active region) of a transistor. For example, a portion of the first semiconductor pattern SC1 may be a channel of the transistor, and another portion may be a source or a drain of the transistor, and another portion may be a connection electrode or a connection signal line.

A source region SE1, a channel region AC1 (e.g., an active region), and a drain region DE1 of the silicon transistor S-TFT may be formed from the first semiconductor pattern SC1. The source region SE1 and the drain region DE1 may extend from the channel region AC1 in opposite directions from each other in a cross sectional view.

A first insulation layer 10 may be disposed on the buffer layer BFL (e.g., disposed directly thereon in the third direction DR3). The first insulation layer 10 may cover the first semiconductor pattern SC1. The first insulation layer 10 may be an inorganic layer. The first insulation layer 10 may be a single-layer silicon oxide layer. In an embodiment, not only the first insulation layer 10 but also an inorganic layer of a circuit layer DP-C to be described later may have a single-layer or multi-layer structure, and may include at least one of the above-described materials. However, embodiments of the present inventive concept are not necessarily limited thereto.

A gate GT1 (e.g., a gate electrode) of the silicon transistor S-TFT is disposed on the first insulation layer 10 (e.g., disposed directly thereon in the third direction DR3). The gate GT1 may be a portion of a metal pattern. The gate GT1 overlaps the channel region AC1 (e.g., in the third direction DR3). In a process of doping the first semiconductor pattern SC1, the gate GT1 may be a mask. A first electrode CE10 of a storage capacitor Cst is disposed on the first insulation layer 10 (e.g., disposed directly thereon in the third direction DR3). However, embodiments of the present inventive concept are not necessarily limited thereto. For example, unlike what is illustrated in FIG. 5, the first electrode CE10 may have an integrated form with the gate GT1.

A second insulation layer 20 may be disposed on (e.g., disposed directly thereon) the first insulation layer 10 and cover the gate GT1. According to an embodiment of the present inventive concept, an upper electrode overlapping the gate GT1 may further be disposed on the second insulation layer 20 (e.g., disposed directly thereon in the third direction DR3). A second electrode CE20 overlapping the first electrode CE10 may be disposed on the second insulation layer 20 (e.g., disposed directly thereon in the third direction DR3). In an embodiment, the upper electrode may also have an integrated form with the second electrode CE20 on a plane.

A second shielding electrode BML2 is disposed on the second insulation layer 20 (e.g., disposed directly thereon in the third direction DR3). The second shielding electrode BML2 may be disposed in correspondence to the oxide transistor O-TFT. For example, the second shielding electrode BML2 may overlap the oxide transistor O-TFT (e.g., in the third direction DR3). However, embodiments of the present inventive concept are not necessarily limited thereto. For example, in an embodiment of the present inventive concept, the second shielding electrode BML2 may be omitted. According to an embodiment of the present inventive concept, the first shielding electrode BML1 may also extend to a lower part of the oxide transistor O-TFT to substitute for the second shielding electrode BML2.

A third insulation layer 30 may be disposed on the second insulation layer 20 (e.g., disposed directly thereon in the third direction DR3). A second semiconductor pattern SC2 may be disposed on the third insulation layer 30 (e.g., disposed directly thereon in the third direction DR3). The second semiconductor pattern SC2 may include a channel region AC2 of the oxide transistor O-TFT. The second semiconductor pattern SC2 may include a metal oxide semiconductor. In an embodiment, the second semiconductor pattern SC2 may include a transparent conductive oxide (TCO) such as indium tin oxide (ITO), indium zinc oxide (IZO), indium gallium zinc oxide (IGZO), zinc oxide (ZnOx), or indium oxide (In203).

The metal oxide semiconductor may include a plurality of regions SE2, AC2, and DE2 divided according to whether the transparent conductive oxide is reduced or not. The region where the transparent conductive oxide is reduced (hereinafter, a reduced region) has higher conductivity than the region where it is not (hereinafter, an unreduced region). The reduced region substantially serves as a source/drain of a transistor or a signal line. The unreduced region substantially corresponds to a semiconductor region (e.g., a channel) of the transistor. For example, a partial region of the second semiconductor pattern SC2 may be the semiconductor region of the transistor, another partial region may be the source region SE2/drain region DE2 of the transistor, and another partial region may be a signal transmission region.

A fourth insulation layer 40 may be disposed on the third insulation layer 30 (e.g., disposed directly thereon in the third direction DR3). As illustrated in FIG. 5, the fourth insulation layer 40 may cover the second semiconductor pattern SC2. According to an embodiment of the present inventive concept, the fourth insulation layer 40 may also be an insulation pattern overlapping a gate GT2 of the oxide transistor O-TFT, and exposed by the source region SE2 and the drain region DE2 of the oxide transistor O-TFT.

The gate GT2 of the oxide transistor O-TFT is disposed on the fourth insulation layer 40 (e.g., disposed directly thereon in the third direction DR3). The gate GT2 of the oxide transistor O-TFT may be a portion of a metal pattern. The gate GT2 of the oxide transistor O-TFT overlaps the channel region AC2 (e.g., in the third direction DR3).

A fifth insulation layer 50 may be disposed on (e.g., disposed directly thereon) the fourth insulation layer 40, and the fifth insulation layer 50 may cover the gate GT2. The first insulation layer 10 to the fifth insulation layer 50 may each be an inorganic layer.

A conductive layer may be disposed on the fifth insulation layer 50 (e.g., disposed directly thereon in the third direction DR3). The conductive layer, according to an embodiment of the present inventive concept, may include a first connection pattern CNP1 and a second connection pattern CNP2. In an embodiment, the first connection pattern CNP1 and the second connection pattern CNP2 may be formed through the same process, and may thus have the same material and the same stacked structure as each other. In an embodiment, the first connection pattern CNP1 may be connected to the drain region DE1 of the silicon transistor S-TFT through a first pixel contact hole PCH1 passing through the first to fifth insulation layers 10, 20, 30, 40, and 50. The second connection pattern CNP2 may be connected to the source region SE2 of the oxide transistor O-TFT through a second pixel contact hole PCH2 passing through the fourth and fifth insulation layers 40 and 50. However, embodiments of the present inventive concept are not necessarily limited thereto and the connection relationships between the first connection pattern CNP1 and the silicon transistor S-TFT and between the second connection pattern CNP2 and the oxide transistor O-TFT may vary.

A sixth insulation layer 60 may be disposed on the fifth insulation layer 50 (e.g., disposed directly thereon in the third direction DR3). A third connection pattern CNP3 may be disposed on the sixth insulation layer 60 (e.g., disposed directly thereon in the third direction DR3). The third connection pattern CNP3 may be connected to the first connection pattern CNP1 through a third pixel contact hole PCH3 passing through the sixth insulation layer 60. A data line DL may be disposed on the sixth insulation layer 60 (e.g., disposed directly thereon in the third direction DR3). A seventh insulation layer 70 may be disposed on (e.g., disposed directly thereon) the sixth insulation layer 60, and cover the third connection pattern CNP3 and the data line DL. In an embodiment, the third connection pattern CNP3 and the data line DL may be formed through the same process, and may thus have the same material and the same stacked structure as each other. In an embodiment, the sixth insulation layer 60 and the seventh insulation layer 70 may each be an organic layer.

In an embodiment, the first shielding electrode BML1, the gate GT1 of the silicon transistor S-TFT, the second electrode CE20, and the gate GT2 of the oxide transistor O-TFT may include molybdenum (Mo), an alloy containing molybdenum, titanium (Ti), or an alloy containing titanium, which have good heat resistance. The first connection pattern CNP1 and the second connection pattern CNP2 may include aluminum having high electrical conductivity. In an embodiment, the first connection pattern CNP1 and the second connection pattern CNP2 may have a three-layer stacked structure of titanium/aluminum/titanium.

A light-emitting element LD may include an anode AE (e.g., a first electrode), a light-emitting layer EML, and a cathode CE (e.g., a second electrode). The anode AE of the light-emitting element LD may be disposed on the seventh insulation layer 70 (e.g., disposed directly thereon in the third direction DR3). The anode AE may be a transmissive electrode, a semi-transmissive electrode, or a reflective electrode. In an embodiment, the anode AE may include a stacked structure of ITO/Ag/ITO stacked in sequence. The position of the anode AE may be switched with the position of the cathode CE.

A pixel-defining film PDL may be disposed on the seventh insulation layer 70 (e.g., disposed directly thereon in the third direction DR3). The pixel-defining film PDL may be an organic layer. The pixel-defining film PDL may have light-absorbing characteristics, and for example, the pixel-defining film PDL may have black color. The pixel-defining film PDL may include a black coloring agent. The black coloring agent may include a black dye or black pigment. The black coloring agent may include carbon black, metal such as chrome, or an oxide thereof. The pixel-defining film PDL may correspond to a light-blocking pattern having light-blocking characteristics.

The pixel-defining film PDL may cover a portion of the anode AE. For example, an opening PDL-OP that exposes a portion of the anode AE may be defined in the pixel-defining film PDL. For example, in an embodiment the pixel-defining film PDL may cover lateral ends of the anode AE and may have an opening PDL-OP exposing a central portion of the anode AE. A light-emitting region LA may be defined in correspondence to the opening PDL-OP. According to an embodiment of the present inventive concept, a hole control layer may be disposed between the anode AE and the light-emitting layer EML (e.g., in the third direction DR3). The hole control layer may include a hole transport layer, and may further include a hole injection layer. An electron control layer may be disposed between the light-emitting layer EML and the cathode CE (e.g., in the third direction DR3). The electron control layer may include an electron transport layer, and may further include an electron injection layer.

An encapsulation layer TFE may cover the light-emitting element LD. In an embodiment, the encapsulation layer TFE may include a first encapsulation insulation layer IL1, a second encapsulation insulation layer IL2, and a third encapsulation insulation layer IL3. However, embodiments of the present inventive concept are not necessarily limited thereto, and the encapsulation layer TFE may further include a plurality of inorganic layers and organic layers.

The first encapsulation insulation layer IL1 may be an inorganic layer. The first encapsulation insulation layer IL1 may prevent external moisture or oxygen from penetrating the light-emitting element LD. For example, in an embodiment the first encapsulation insulation layer IL1 may include silicon nitride, silicon oxide, or a compound thereof. The first encapsulation insulation layer IL1 may be formed through a chemical vapor deposition process.

The second encapsulation insulation layer IL2 may be an organic layer. The second encapsulation insulation layer IL2 may be disposed on (e.g., disposed directly thereon) the first encapsulation insulation layer IL1 to be in direct contact with the first encapsulation insulation layer IL1. The second encapsulation insulation layer IL2 may provide a planarized surface onto the first encapsulation insulation layer IL1. A curve formed on an upper surface of the first encapsulation insulation layer IL1, particles present on the first encapsulation insulation layer IL1, or the like may be covered by the second encapsulation insulation layer IL2, so that it may be possible to prevent the surface condition of the upper surface of the first encapsulation insulation layer IL1 from influencing the components to be formed on the second encapsulation insulation layer IL2. In addition, the second encapsulation insulation layer IL2 may relieve stress between layers which are in direct contact therewith. In an embodiment, the second encapsulation insulation layer IL2 may be formed through a solution process such as spin coating, slit coating, and an inkjet process.

A third encapsulation insulation layer IL3 is disposed on (e.g., disposed directly thereon) the second encapsulation insulation layer IL2 and covers the second encapsulation insulation layer IL2. The third encapsulation insulation layer IL3 may be stably formed on a relatively planarized surface compared to an embodiment in which it is disposed on the first encapsulation insulation layer IL1. The third encapsulation insulation layer IL3 encapsulates moisture and the like, released from the second encapsulation insulation layer IL2, to prevent the moisture and the like from flowing outwards.

In an embodiment, the third encapsulation insulation layer IL3 may be optically transparent. For example, the third encapsulation insulation layer IL3 may have a visual-light transmittance of about 90% or higher. The third encapsulation insulation layer IL3 may have a higher light transmittance than that of the first encapsulation insulation layer IL1. The third encapsulation insulation layer IL3 may be an inorganic layer. In an embodiment, the third encapsulation insulation layer IL3 may include silicon oxide (SiOx) or silicon oxynitride (SiON). In an embodiment, the third encapsulation insulation layer IL3 may be formed through a chemical vapor deposition process. In an embodiment, the first encapsulation insulation layer IL1, the second encapsulation insulation layer IL2, and the third encapsulation insulation layer IL3 may each include a plurality of layers, and are not necessarily limited to any one embodiment.

An input-sensing layer ISL may include at least one conductive layer (e.g., at least one sensor conductive layer) and at least one insulating layer (e.g., at least one sensor insulating layer). In an embodiment, the input-sensing layer ISL may include a first insulating layer IS-IL1, a first conductive layer ICL1, a second insulating layer IS-IL2, a second conductive layer ICL2, and a third insulating layer IS-IL3. FIG. 5 briefly illustrates a conductive line of the first conductive layer ICL1 and a conductive line of the second conductive layer ICL2.

The first insulating layer IS-IL1 may be directly disposed on the display panel DP (e.g., in the third direction DR3). In an embodiment, the first insulating layer IS-IL1 may be an inorganic layer including at least any one of silicon nitride, silicon oxynitride, or silicon oxide. The first conductive layer ICL1 and the second conductive layer ICL2 may each have a single-layer structure, or a structure of multiple layers stacked along a third direction DR3. The first conductive layer ICL1 and the second conductive layer ICL2 may include conductive lines that define an electrode in a mesh form. In an embodiment, the conductive line of the first conductive layer ICL1 and the conductive line of the second conductive layer ICL2 may be connected through a contact hole passing through the second insulating layer IS-IL2, or may not be connected. For example, the connection relationship between the conductive line of the first conductive layer ICL1 and the conductive line of the second conductive layer ICL2 may be determined according to the type of a sensor forming the input-sensing layer ISL.

The first conductive layer ICL1 and the second conductive layer ICL2 in a single-layer structure may each include a metal layer or a transparent conductive layer. In an embodiment, the metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnOx), or indium zinc tin oxide (IZTO). In addition, the transparent conductive layer may include a conductive polymer such as PEDOT, a metal nanowire, graphene, etc.

The first conductive layer ICL1 and the second conductive layer ICL2 in a multi-layer structure may include metal layers. In an embodiment, the metal layers may have a three-layer structure of, for example, titanium/aluminum/titanium. The conductive layer in the multi-layer structure may include at least one metal layer and at least one transparent conductive layer. The second insulating layer IS-IL2 may be disposed between the first conductive layer ICL1 and the second conductive layer ICL2 (e.g., in the third direction DR3). The third insulating layer IS-IL3 may cover the second conductive layer ICL2. However, embodiments of the present inventive concept are not necessarily limited thereto. For example, in an embodiment of the present inventive concept, the third insulating layer IS-IL3 may be omitted. The second insulating layer IS-IL2 and the third insulating layer IS-IL3 may each include an inorganic layer or an organic layer.

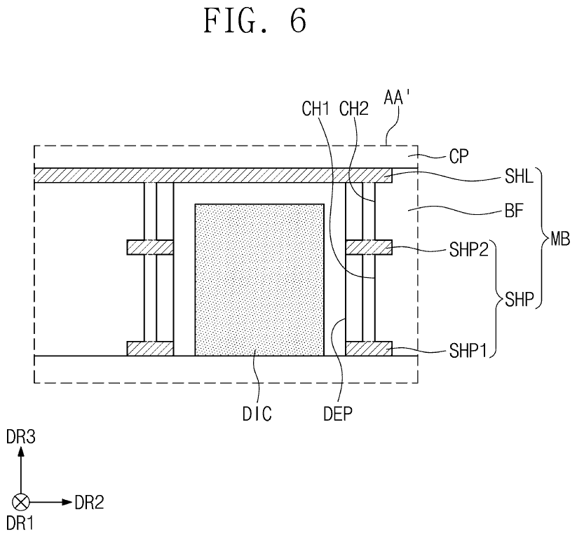

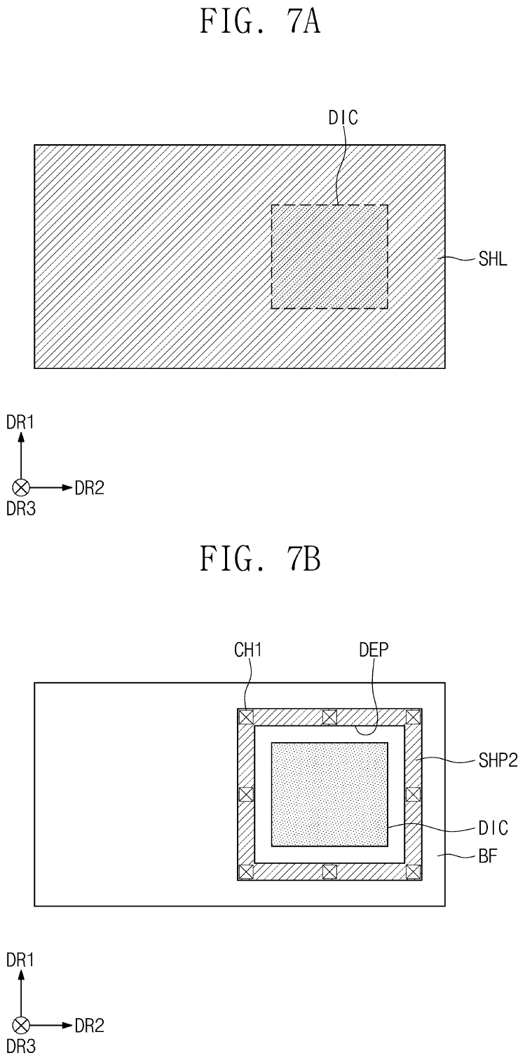

FIG. 6 is an enlarged view of region AA′ illustrated in FIG. 4B. In particular, FIG. 6 is an enlarged view illustrating a main circuit board MB and a driving chip DIC according to an embodiment of the present inventive concept. FIGS. 7A and 7B are plan views of region AA′ of FIG. 6 viewed from a third direction DR3.

Referring to FIG. 6, in an embodiment the main circuit board MB may include a base film BF, a shielding layer SHL, and a shielding pattern SHP. The main circuit board MB may be provided in multiple layers. The shielding layer SHL and the shielding pattern SHP may each be one layer among the multiple layers.

The base film BF may include an insulation layer having a single-layer or multi-layer structure. The base film BF may include a plurality of wires therein. The plurality of wires may be disposed between a plurality of insulation layers. For example, in an embodiment the plurality of insulation layers may include a synthetic resin material, for example, polyimide or an inorganic material, for example, silicon nitride, silicon oxide, or a compound thereof.

Referring to FIGS. 6 and 7A together, the shielding layer SHL may be in direct contact with a cover panel CP and disposed under the cover panel CP (e.g., in a direction opposite to the third direction DR3). The shielding layer SHL may overlap a recessed part DEP on a plane. In an embodiment, the shielding layer SHL may provide a lower surface of the recessed part DEP (e.g., when the connection circuit board CF is in a bent state). Since the shielding layer SHL overlaps the recessed part DEP on a plane, the shielding layer SHL may overlap the driving chip DIC, disposed in the recessed part DEP, on a plane. For example, in an embodiment the shielding layer SHL may overlap an entirety of the recessed part DEP, on a plane.

The shielding layer SHL may protect the driving chip DIC from external static electricity. In an embodiment, the shielding layer SHL may include highly conductive metal, and may thus absorb or reflect external radio waves. For example, in an embodiment the shielding layer SHL may include iron or nickel to absorb an external magnetic field, or may include copper or aluminum to reflect an external magnetic field. For example, the shielding layer SHL may overlap the driving chip DIC on a plane, so that the driving chip DIC may be protected from the external static electricity through the shielding layer SHL. However, embodiments of the present inventive concept are not necessarily limited thereto, and a magnetic field and the like, generated from the driving chip DIC, may be shielded not to be emitted to the outside (e.g., the external environment).

Referring to FIGS. 6 and 7B together, the shielding pattern SHP may be disposed along a border of the recessed part DEP. For example, a width (e.g., in a plan view) of the recessed part DEP may be greater than a width (e.g., in a plan view) of the driving chip DIC disposed therein. In an embodiment, the shielding pattern SHP may be arranged to surround the driving chip DIC disposed in the recessed part DEP, on a plane. For example, the shielding pattern SHP may be arranged along a border of the recessed part DEP (e.g., in a plan view). In an embodiment, the shape of the shielding pattern SHP may correspond to the shape of the driving chip DIC. For example, in an embodiment in which the driving chip DIC has a quadrilateral shape on a plane, the shielding pattern SHP may have a quadrilateral ring shape in correspondence thereto. However, embodiments of the present inventive concept are not necessarily limited thereto, and the shielding pattern SHP may have a shape of a circle ring or a polygonal ring that is more than a pentagon or may have various other shapes.

According to an embodiment of the present inventive concept, the shielding pattern SHP may be provided in plurality and may be arranged in a recessed direction of the recessed part DEP which is a direction that the recessed part DEP is recessed from a surface of the main circuit board MB. For example, in an embodiment the shielding pattern SHP may include a first shielding pattern SHP1 and a second shielding pattern SHP2 arranged along the third direction DR3. The first shielding pattern SHP1 and the second shielding pattern SHP2 may be disposed to be spaced apart from each other in the third direction DR3. In an embodiment, the first shielding pattern SHP1 and the second shielding pattern SHP2 may have the same shape as each other on a plane. For example, the first shielding pattern SHP1 and the second shielding pattern SHP2 may overlap each other on a plane.

The first shielding pattern SHP1 and the second shielding pattern SHP2 may each surround the driving chip DIC (e.g., in a plan view). For example, the first shielding pattern SHP1 and the second shielding pattern SHP2 may each overlap the driving chip DIC in a first direction DR1 and a second direction DR2. The first shielding pattern SHP1 and the second shielding pattern SHP2 may each protect the driving chip DIC from external static electricity. In an embodiment, the first shielding pattern SHP1 and the second shielding pattern SHP2 may include highly conductive metal, and may thus absorb or reflect external radio waves.

In an embodiment, the first shielding pattern SHP1 and the second shielding pattern SHP2 may include the same material as each other. However, embodiments of the present inventive concept are not necessarily limited thereto, and the first shielding pattern SHP1 and the second shielding pattern SHP2 may each include the same material as that of the shielding layer SHL. For example, in an embodiment the first shielding pattern SHP1 and the second shielding pattern SHP2 may each include iron or nickel to absorb an external magnetic field, or may each include copper or aluminum to reflect an external magnetic field.

The first shielding pattern SHP1 and the second shielding pattern SHP2 may be electrically connected to each other. In addition, the second shielding pattern SHP2 and the shielding layer SHL may be electrically connected to each other. For example, in an embodiment the first shielding pattern SHP1 and the second shielding pattern SHP2 may be electrically connected to each other through a first contact hole CH1 formed by passing through the base film BF (e.g., in the third direction DR3), and the second shielding pattern SHP2 and the shielding layer SHL may be electrically connected to each other through a second contact hole CH2 formed by passing through the base film BF (e.g., in the third direction DR3). As illustrated in an embodiment of FIG. 7B, the first contact hole CH1 may be provided in plurality, and the plurality of first contact holes CH1 may be arranged along the border of the recessed part DEP (e.g., in a plan view). In an embodiment, the second contact hole CH2 may also be provided in plurality, and the plurality of second contact holes CH2 may be arranged along the border of the recessed part DEP (e.g., in a plan view).

Referring to FIGS. 6 to 7B together, since the driving chip DIC is disposed in the recessed part DEP which is defined in the main circuit board MB according to an embodiment of the present inventive concept, a separate cover space, etc. for protecting the driving chip DIC may not be formed, so that it may be possible to simplify the manufacturing process of the display device DD (see FIG. 2). In addition, since the main circuit board MB according to an embodiment of the present inventive concept includes the shielding layer SHL, overlapping the driving chip DIC on a plane, and the first shielding pattern SHP1 and the second shielding pattern SHP2 surrounding the driving chip DIC on a plane, the driving chip DIC may be protected from external static electricity. Consequently, a display device DD with increased reliability may be provided.

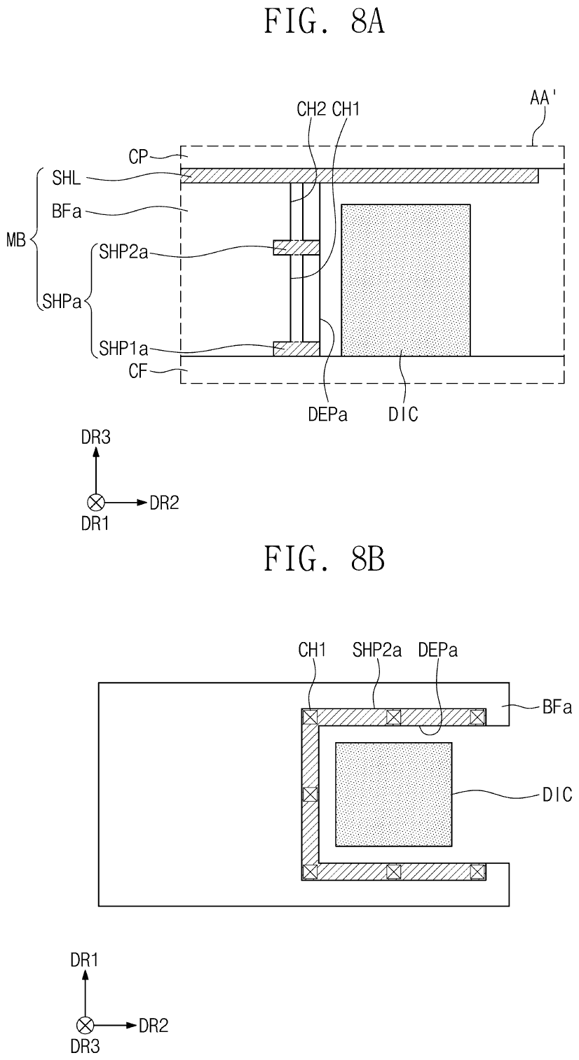

FIG. 8A is an enlarged view illustrating a portion of a display device according to an embodiment of the present inventive concept. For example, FIG. 8A is an enlarged view of region AA′ illustrated in FIG. 4B. FIG. 8B is a plan view of region AA′ of FIG. 8A viewed from a third direction DR3.

Referring to FIGS. 8A and 8B together, in an embodiment a main circuit board MBa may include a base film BFa, a shielding layer SHL, and a shielding pattern SHPa. A recessed part DEPa may be defined in the main circuit board MBa, and a driving chip DIC may be disposed in the recessed part DEPa. The recessed part DEPa may be recessed from an upper surface and side surface of the base film BFa (e.g., when the connection circuit board CF is in an unbent state).

According to an embodiment of the present inventive concept, the recessed part DEPa may be recessed from three surfaces of the upper surface of the base film BFa. For example, the recessed part DEPa may be formed by being recessed in an opposite direction of the third direction DR3 with respect to the upper surface of the base film BFa, and at the same time, recessed in an opposite direction of a second direction DR2 with respect to the side surface of the base film BFa (e.g., when the connection circuit board CF is in an unbent state). The driving chip DIC may be exposed to the outside in the second direction DR2 (e.g., when the connection circuit board CF is in a bent state) which is an opposite direction in which the main circuit board extends MB.

The shielding pattern SHPa may be disposed along a border of the recessed part DEPa. For example, the shielding pattern SHPa may be disposed to surround the driving chip DIC, disposed in the recessed part DEPa, on a plane. Since the recessed part DEPa is formed by being recessed in the opposite direction of the second direction DR2 with respect to the side surface of the base film BFa, the shielding pattern SHPa may be formed with a right-side portion being omitted on a plane as compared to an embodiment shown in FIG. 6.

In an embodiment, the shielding pattern SHPa may include a first shielding pattern SHPla and a second shielding pattern SHP2a disposed in the third direction DR3. The first shielding pattern SHPla and the second shielding pattern SHP2a may be disposed to be spaced apart from each other in the third direction DR3. The first shielding pattern SHPla and the second shielding pattern SHP2a may have the same shape as each other on a plane. For example, the first shielding pattern SHPla and the second shielding pattern SHP2a may overlap each other on a plane.

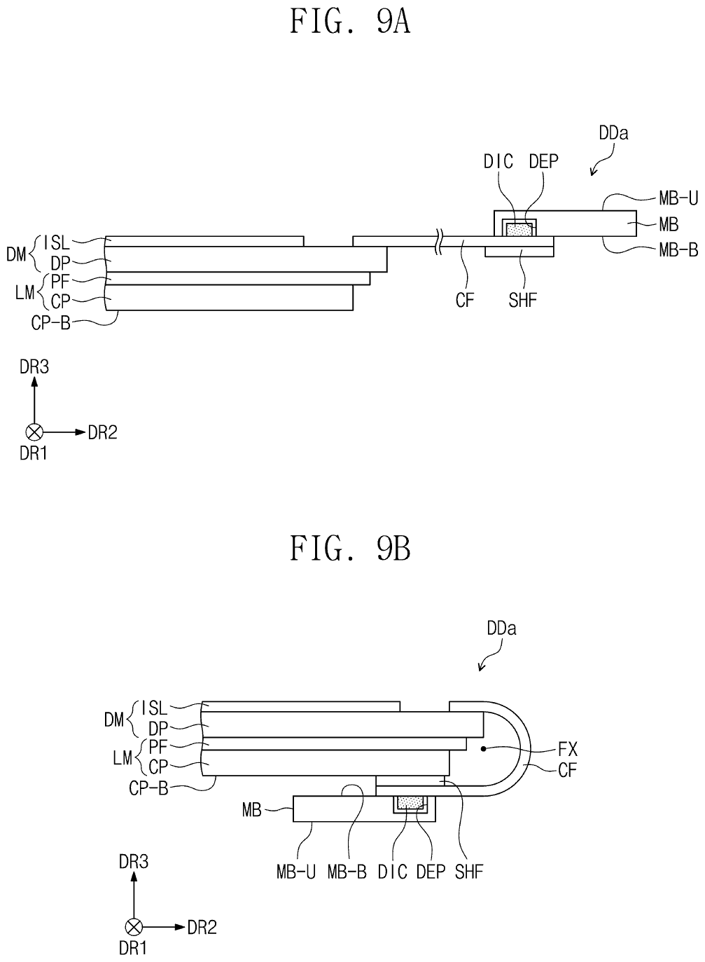

FIGS. 9A and 9B are cross-sectional views each illustrating a display device according to an embodiment of the present inventive concept. Hereinafter, duplicate contents or those previously described may be omitted for economy of description.

Referring to FIGS. 9A and 9B together, a main circuit board MB may be disposed on an upper surface of a connection circuit board CF (e.g., disposed directly thereon in the third direction DR3). The connection circuit board CF may be bendable in a direction towards a rear surface of a display panel DP with a predetermined curvature. For example, in an embodiment the connection circuit board CF may be bendable with respect to a bending axis FX parallel to a first direction DR1. At this time, the main circuit board MB may be disposed on the rear surface of the display panel DP when the connection circuit board CF is in a bent state. Unlike the display device DD illustrated in FIG. 4B, a display device DDa illustrated in FIG. 9B may include the main circuit board MB which is disposed to be spaced apart from a rear surface CP-B of a cover panel CP in a third direction DR3. The rear surface CP-B of the cover panel CP may be in direct contact with a shielding film SHF. For example, the shielding film SHF may be disposed directly between the rear surface CP-B of the cover panel CP and the connection circuit board CF (e.g., in the third direction DR3) when the connection circuit board CF is in a bent state.

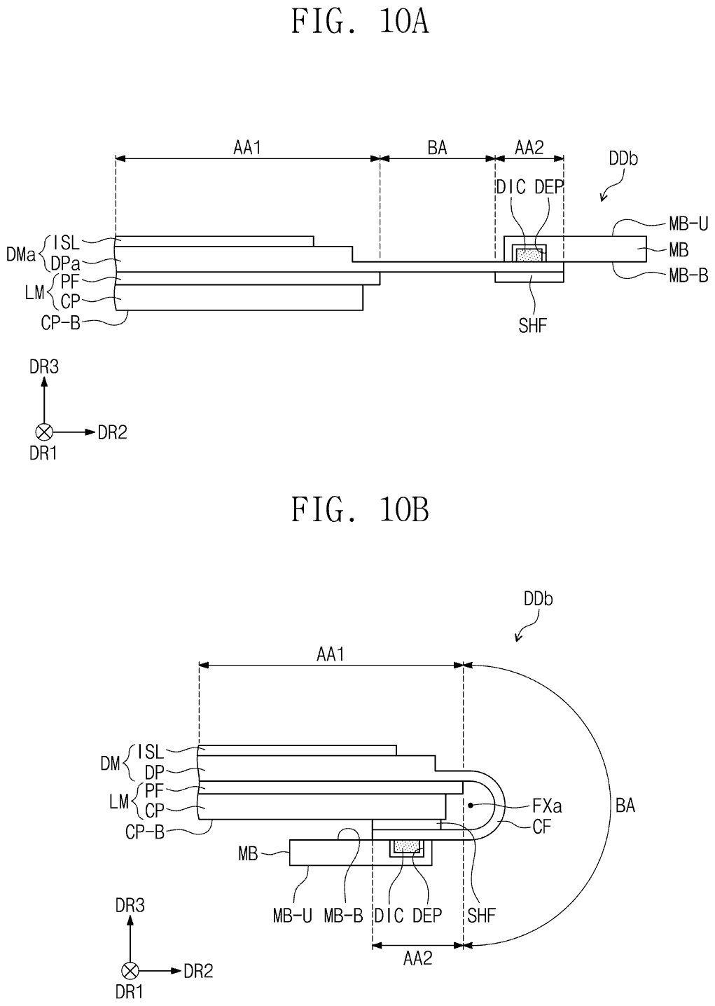

FIGS. 10A and 10B are cross-sectional views each illustrating a display device according to an embodiment of the present inventive concept.

Referring to FIGS. 10A and 10B together, a display device DDb according to an embodiment of the present inventive concept may include a display panel DPa which is bendable. For example, the display panel DPa may include a first region AA1, a second region AA2, and a bending region BA that are distinguished from each other (e.g., spaced apart from each other) in a second direction DR2. As illustrated in FIG. 10A, when the display device DDb is in an unfolded state, at least a portion of the first region AA1 and the second region AA2 of the display panel DPa, fitted in the display device DDb, are disposed on different planes. For example, at least a portion of an upper surface of the first region AA1 and the second region AA2 of the display panel DPa are disposed on different planes from each other when the display device DDb is in an unfolded state. The bending region BA is disposed between the first region AA1 and the second region AA2 (e.g., in the second direction DR2 when the display panel DPa is in an unbent state).

The first region AA1 may correspond to a display region DA including the pixel PX illustrated in FIG. 3. The bending region BA may be bendable with respect to a bending axis FXa parallel to a first direction DR1. A driving chip DIC may be mounted in the second region AA2. A main circuit board MB (e.g., a circuit board) may be connected to one side of the second region AA2. For example, in the second region AA2, the driving chip DIC may be disposed in a recessed part DEP that is defined in the main circuit board MB. The main circuit board MB may be disposed on an upper surface of the second region AA2 of the display panel DPa (e.g., disposed directly thereon in the third direction DR3) when the display panel DPa is in an unbent state.

The length of the bending region BA and the second region AA2 on a second direction DR2 may be less than the length of the first region AA1. The second region AA2 and the bending region BA may be a partial region of the non-display region NDA (see FIG. 3).

A driving chip may be disposed in a recessed part which is defined in a main circuit board included in a display device according to an embodiment of the present inventive concept. Accordingly, a separate cover space and the like for protecting the driving chip may not be formed, thereby simplifying a manufacturing process of the display device according to an embodiment of the present inventive concept.

In addition, since the main circuit board according to an embodiment of the present inventive concept includes a shielding layer overlapping the driving chip on a plane and a shielding pattern surrounding the driving chip on a plane, the driving chip may be protected from external static electricity. Consequently, a display device with increased reliability may be provided.

### The Electronic Device

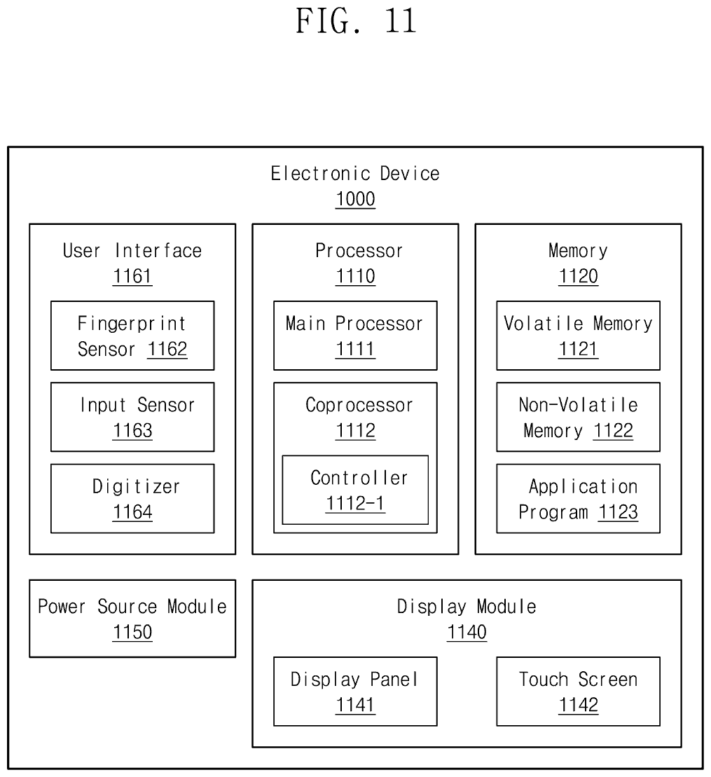

FIG. 11 is a diagram illustrating an electronic device according to an embodiment of the present invention. Referring to FIG. 11, the electronic device 1000 according to one embodiment of the present invention may output various information (e.g., images, text, music, etc.) through a display module 1140, which, for example, may correspond to the electronic device ED shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the electronic device ED shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the electronic device ED shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although the embodiments of the present inventive concept have been described, it is understood that the present inventive concept should not be limited to these embodiments but various changes and modifications can be made by one ordinary skilled in the art within the spirit and scope of the present inventive concept as hereinafter claimed.

Therefore, the technical scope of the present inventive concept should not be limited to the contents described in the detailed description of the specification, but should be defined by the claims.

What is claimed is:

1. A display device comprising:
a display panel;
a main circuit board having a recessed part that is recessed in a thickness direction of the display panel; and
a connection circuit board electrically connected to the display panel on a first side of the connection circuit board and electrically connected to the main circuit board on a second side of the connection circuit board opposite to the first side,
a driving chip is mounted on the second side of the connection circuit board and is disposed in the recessed part,
wherein the main circuit board includes a shielding layer overlapping the recessed part.

2. The display device of claim 1, wherein the main circuit board further comprises a shielding pattern surrounding the driving chip on a plane.

3. The display device of claim 2, wherein:
the shielding pattern includes a plurality of shielding patterns; and
the plurality of shielding patterns is arranged in a recessed direction of the recessed part.

4. The display device of claim 3, wherein the main circuit board includes a contact hole connecting the plurality of shielding patterns to each other.

5. The display device of claim 4, wherein:
the contact hole includes a plurality of contact holes; and
the plurality of contact holes is arranged along a border of the recessed part.

6. The display device of claim 2, wherein:
a width of the recessed part is greater than a width of the driving chip; and
the shielding pattern is disposed along a border of the recessed part.

7. The display device of claim 1, wherein:
the main circuit board extends in an extending direction; and
the driving chip is exposed to an outside in an opposite direction of the extending direction of the main circuit board.

8. The display device of claim 1, wherein:
the connection circuit board is bendable with respect to a virtual axis extending in a first direction, wherein the main circuit board is disposed under the display panel in a bent state.

9. The display device of claim 8, further comprising a cover panel disposed under the display panel,
wherein the main circuit board is in direct contact with the cover panel.

10. The display device of claim 1, wherein:
the driving chip is disposed on an upper surface of the connection circuit board; and
the display device further comprises a shielding film disposed on a lower surface of the connection circuit board facing the upper surface of the connection circuit board.

11. The display device of claim 1, wherein a depth of the recessed part is greater than a thickness of the driving chip.

12. The display device of claim 1, wherein the shielding layer overlaps an entirety of the recessed part.

13. A display device comprising:
a display panel;
a main circuit board having a recessed part that is recessed in a thickness direction of the display panel; and
a connection circuit board electrically connected to the display panel on a first side of the connection circuit board and electrically connected to the main circuit board on a second side of the connection circuit board opposite to the first side,
a driving chip is mounted on the second side of the connection circuit board and is disposed in the recessed part,
wherein the main circuit board includes a shielding pattern surrounding the driving chip on a plane.

14. The display device of claim 13, wherein:
the shielding pattern includes a plurality of shielding patterns; and
the plurality of shielding patterns is arranged in a recessed direction of the recessed part.

15. The display device of claim 14, wherein the main circuit board includes a contact hole connecting the plurality of shielding patterns to each other.

16. The display device of claim 14, wherein:
a width of the recessed part is greater than a width of the driving chip; and
the shielding pattern is disposed along a border of the recessed part.

17. The display device of claim 13, wherein the main circuit board further comprises a shielding layer overlapping the recessed part.

18. The display device of claim 17, wherein the shielding layer and the shielding pattern comprise a same material as each other.

19. The display device of claim 13, wherein a depth of the recessed part is greater than a thickness of the driving chip.

20. An electronic device comprising:
a display device;
an electronic module overlapping the display device; and
a housing accommodating the display device,
wherein the display device comprising:
a display panel;
a main circuit board having a recessed part that is recessed in a thickness direction of the display panel; and
a connection circuit board electrically connected to the display panel on a first side of the connection circuit board and electrically connected to the main circuit board on a second side of the connection circuit board opposite to the first side,
a driving chip is mounted on the second side of the connection circuit board and is disposed in the recessed part,
wherein the main circuit board includes a shielding layer overlapping the recessed part.
